(19) United States
(12) Patent Application Publication
(10) Pub. No.: US 2026/0280242 A1
(43) Pub. Date: Sep. 17, 2026

(54) CAPACITOR BANK CONTROLLER

(71) Applicant: Eaton Intelligent Power Limited, Dublin (IE)

(72) Inventors: Rajan TRIBHUVAN, Maharastra (IN); Troy D. HEDLUND, Rogers, MN (US); Jihad RAMDENE, Pittsburgh, PA (US); Kevin ALLMARAS, Carrington, ND (US); Manishkumar SHARMA, Maharashtra (IN); Michael MANNING, Finksburg, MD (US)

(73) Assignee: Eaton Intelligent Power Limited, Dublin (IE)

(21) Appl. No.: 19/566,239

(22) Filed: Mar. 13, 2026

(30) Foreign Application Priority Data
Mar. 14, 2025 (IN) 202511023081

(51) Int. Cl. H02B 1/44; H02B 1/48; H05K 5/02; H05K 5/03; H05K 5/04

(52) U.S. Cl. CPC H02B 1/44; H02B 1/48; H05K 5/0204; H05K 5/0226; H05K 5/0286; H05K 5/03; H05K 5/04

(57) ABSTRACT

A capacitor bank control enclosure including an outer housing having an inner door assembly that separates an interior of the outer housing into forward and rearward portions. The inner door assembly selectively blocks access to the rearward portion of the interior. At least a modular PCB closure is mounted in the rearward portion. The modular PCB closure is removable from the outer housing as a unit without disassembling the modular PCB closure. In various examples, a radio, antenna connections, input cables, and other components also can be mounted within the rearward portion of the interior. An electronic display can be carried by the inner door assembly.

### CROSS-REFERENCE TO RELATED PAPERS

This application claims the benefit of Indian Provisional Application No. 202511023081, filed Mar. 14, 2025, the disclosure of which is hereby incorporated herein by reference in its entirety.

### BACKGROUND

Capacitor banks are used throughout the electric power distribution industry. Typically, capacitor banks act to maintain a relatively constant power factor over a portion of an electric transmission or distribution system during periods of heavy loads. For example, in a distribution system that feeds a residential area, loads may increase unexpectedly due to a sudden increase in air conditioner use in hot weather. Capacitor banks assist in correcting the power factor of the system and maintaining the system voltage during load variations. Capacitor banks are used both in distribution systems and transmission systems—in any location where an increase or decrease in electrical load may occur.

### SUMMARY

A capacitor bank control enclosure includes an outer housing; an inner door assembly configured to mount within the outer housing; and a modular PCB closure configured to mount within the outer housing. The outer housing includes a base and a cover that cooperate to define an interior. The cover is movable relative to the base between an open position and a closed position. The inner door assembly includes an inner door that divides the interior of the outer housing into a front portion and a rear portion. The inner door is movable relative to the outer housing between a blocking position and an unblocking position. The inner door blocks access to the rear portion of the interior when in the blocking position. The inner door allows access to the rear portion of the interior when in the unblocking position. The modular door assembly carries an electronic display arrangement accessible from the front portion of the interior. A modular PCB closure is configured to mount within the rear portion of the outer housing. The modular PCB closure includes a closed housing containing a circuit board and a capacitor bank controller mounted to the circuit board. The modular PCB closure is removable from the outer housing as a unit while the inner door is disposed in the unblocking position.

In certain implementations, the closed housing of the modular PCB closure includes metallic cover to provide Faraday cage.

In certain implementations, a radio mounting station disposed in the rear portion of the outer housing. In certain examples, the radio mounting station is disposed on the modular PCB closure. In certain examples, a radio removably disposed at the radio mounting station.

In certain implementations, the inner door assembly includes an elongate bracket to which the inner door is mounted. The elongate bracket is removably mountable to the outer housing. The inner door is movable between the unblocking and blocking positions relative to the elongate bracket. In certain examples, the elongate bracket is slidably mounted to the outer housing using dovetails.

In certain implementations, a breaker switch is mountable in the rear portion of the outer housing interior. In certain examples, the breaker switch is accessible from the front portion of the interior even when the inner door is disposed in the blocking position through an aperture defined in the inner door.

A variety of additional inventive aspects will be set forth in the description that follows. The inventive aspects can relate to individual features and to combinations of features. It is to be understood that both the forgoing general description and the following detailed description are exemplary and explanatory only and are not restrictive of the broad inventive concepts upon which the embodiments disclosed herein are based.

### BRIEF DESCRIPTION OF THE DRAWINGS

The accompanying drawings, which are incorporated in and constitute a part of the description, illustrate several aspects of the present disclosure. A brief description of the drawings is as follows:

FIG. 1 is a front perspective view of an example capacitor bank control enclosure configured in accordance with the principles of the present disclosure, the capacitor bank control enclosure being mounted to a bracket.

FIG. 2 is a rear perspective view of the capacitor bank control enclosure of FIG. 1 exploded away from the bracket.

FIG. 3 is a schematic diagram of the example capacitor bank control enclosure of FIG. 1.

FIG. 4 is a front perspective view of the capacitor bank control enclosure of FIG. 1 with a front cover removed for ease in viewing an inner door assembly having an inner door disposed in a blocking position.

FIG. 5 shows the front cover of the capacitor bank control enclosure of FIG. 1 moved to an open position and the inner door of the inner door assembly of FIG. 4 moved to an unblocking position.

FIG. 6 is another perspective view of the capacitor bank control enclosure of FIG. 5 with a lock handle shown exploded away from a lock station.

FIG. 7 shows an example modular PCB closure mounted to a base of the capacitor bank control enclosure of FIG. 1.

FIG. 8 shows the modular PCB closure of FIG. 7 exploded away from the base.

FIG. 9 is a schematic diagram of the modular PCB closure of FIG. 7.

FIG. 10 is an exploded view of the inner door assembly of FIG. 4.

FIG. 11 is a perspective view of an example base suitable for the capacitor bank control enclosure of FIG. 1, the base shown empty for ease in viewing.

FIG. 12 shows first and second brackets exploded outwardly from the base of FIG. 11, the first bracket forming part of the inner door assembly of FIG. 4 and the second bracket carrying a breaker switch.

FIG. 13 is a perspective view of the second bracket of FIG. 12.

FIG. 14 shows an example cable entry panel and an example radio exploded outwardly from the base of the capacitor bank control enclosure of FIG. 1.

FIG. 15 shows the cable entry panel and radio of FIG. 14 mounted within the base.

FIG. 16 is a perspective view of an example locking handle suitable for locking the cover to the base of the capacitor bank control enclosure of FIG. 1.

FIG. 17 is a cross-sectional view of the capacitor bank control enclosure of FIG. 1 taken along the 17-17-17 plane of FIG. 2.

FIG. 18 is a perspective view of the capacitor bank control enclosure of FIG. 1 with the cover shown in the open position and the inner door shown in the unblocking position and engaged with the cover.

FIG. 19 shows a first part of a hinge arrangement between the base and the cover of the capacitor bank control enclosure of FIG. 1.

FIG. 20 shows a first hinge member of the first part of the hinge arrangement of FIG. 19, the first hinge member defining a notch.

FIG. 21 shows a second part of the hinge arrangement between the base and the cover of the capacitor bank control enclosure of FIG. 1.

FIG. 22 shows a second hinge member of the second part of the hinge arrangement of FIG. 21, the second hinge member defining a protrusion.

FIG. 23 is another view of the second hinge member of FIG. 22.

FIG. 24 shows the first and second hinge members of FIGS. 20 and 22 when the cover is disposed in the closed position.

FIG. 25 shows the first and second hinge members of FIG. 24 when the cover is disposed and locked in the open position.

FIG. 26 shows an example rearwardly-facing handle of the base.

FIG. 27 shows an example pocket for the cover locking arrangement.

FIG. 28 shows the locking handle of FIG. 16 mounted at the pocket of FIG. 27.

### DETAILED DESCRIPTION

Reference will now be made in detail to exemplary aspects of the present disclosure that are illustrated in the accompanying drawings. Wherever possible, the same reference numbers will be used throughout the drawings to refer to the same or like parts.

A capacitor bank control enclosure 100 is configured to operate utility distribution feeder capacitors within an energy distribution management system. In general, banks of such capacitors can assist in voltage regulation, reduce power losses by locally compensating for reactive power, provide system relief, and/or provide transformer relief. The capacitor banks and associated controller can be housed within an enclosure 100 to protect them from the surrounding environment. For example, the enclosure 100 may provide water ingress protection, salt ingress protection, or otherwise protect against contaminants. In certain examples, the enclosure 100 protects against ultraviolet light exposure. In an example, the enclosure 100 has a NEMA rating of 3R. Other configurations are possible (e.g., NEMA 4X rating, IP65, etc.).

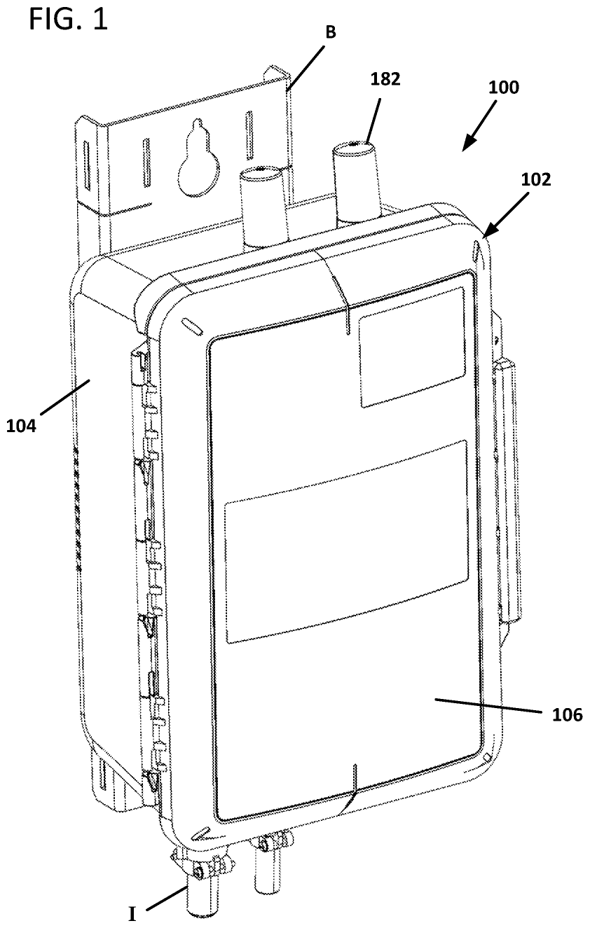

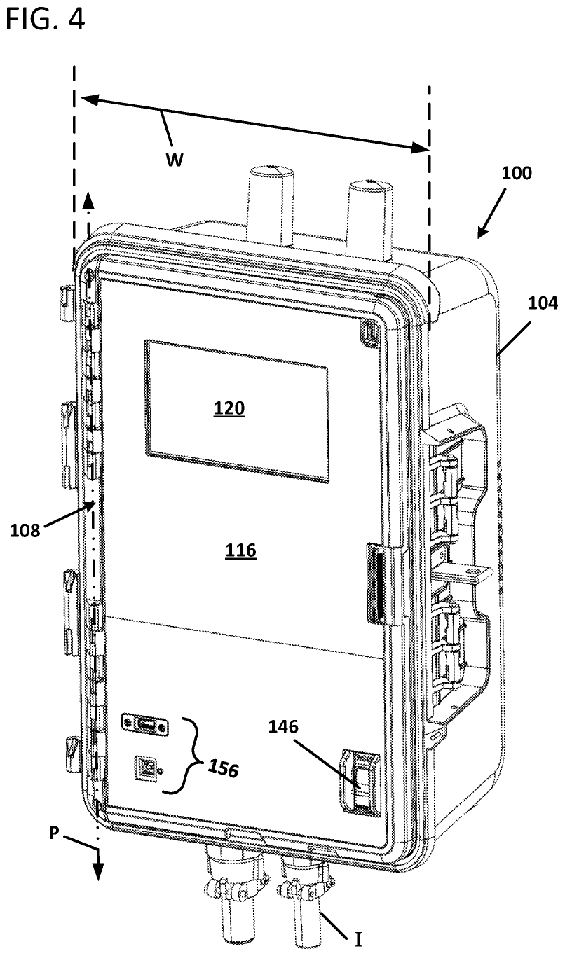

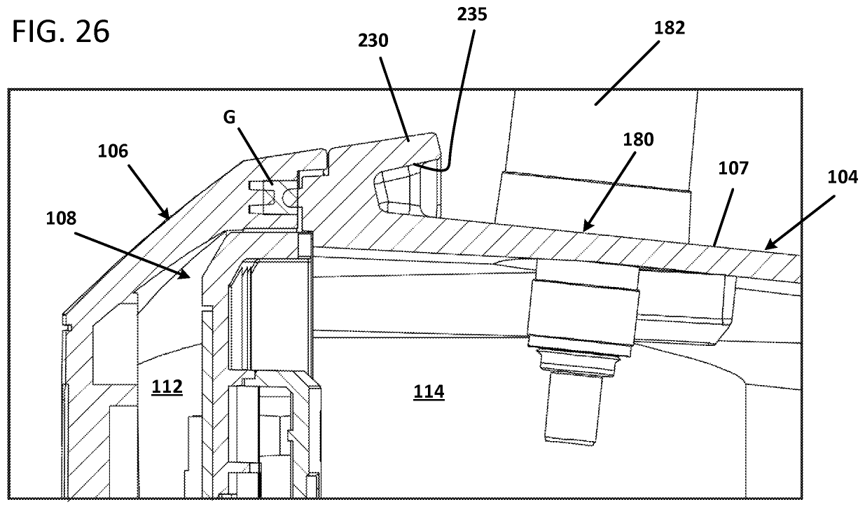

Referring to FIGS. 1-3, the enclosure 100 includes an outer housing 102, which includes a base 104 and a cover 106 that cooperate to define an interior 110. The base 104 has a width W extending between opposite first and second sides 101, 103; has a height H extending between a bottom 105 and a top 107; and has a depth D extending between a rear wall 109 and an open front. The cover 106 mounts at the front of the base 104 to selectively cover the open front to enclose the interior 110. The cover 106 is movable relative to the base 104 between a closed position (e.g., see FIG. 1) and an open position (e.g., see FIG. 4). The cover 106 blocks access to the interior 110 when the cover 106 is disposed in the closed position. The cover 106 allows access to the interior 110 when the cover 106 is disposed in the open position. In certain examples, a gasket G seals between the cover 106 and the base 104 (e.g., see FIG. 26).

The base 104 is configured to mount to a pole, wall, or other support structure. For example, a bracket B may facilitate mounting the base 104 to the support structure. In certain examples, the bracket B mounts to the rear wall 109 of the base 104. In certain implementations, the base 104 includes a handle 230. In certain examples, the base 104 includes a rear-facing handle 230. In certain example, the handle 230 includes a rearwardly extending lip that defines a concave pocket 235 to form a handhold for a user. In certain examples, the rearwardly extending lip is disposed at the top 107 of the base 104. The base 104 defines a cable access port 184 through which one or more input cables I can enter the enclosure 100. In certain examples, the cable access port 184 is defined through the bottom 105 of the base 104.

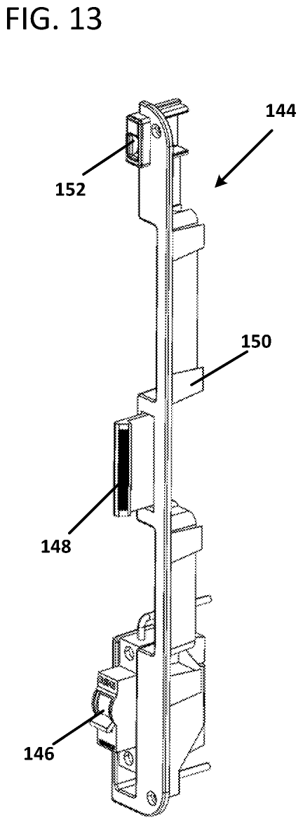

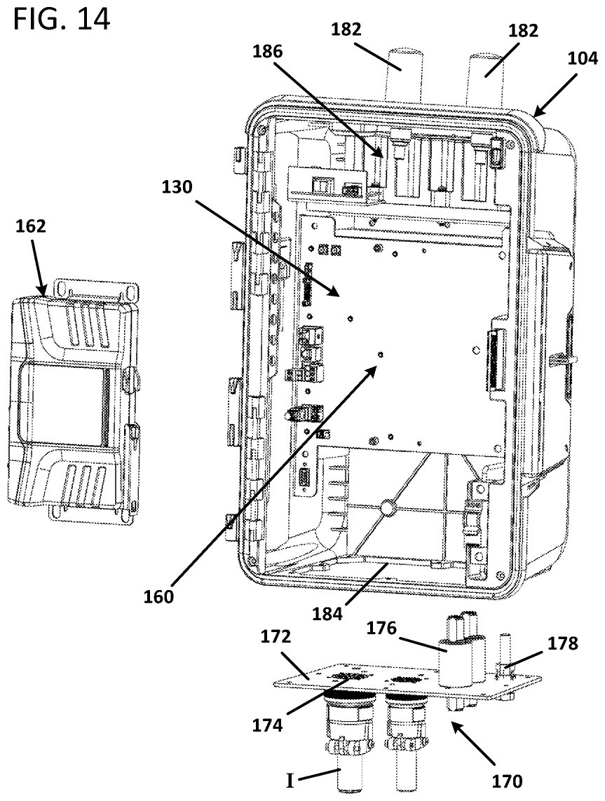

In certain implementations, an entry plate arrangement 170 is mountable at the cable access port 184 (e.g., see FIG. 14). The entry plate arrangement 170 includes one or more components mounted to an entry plate 172. The one or more input cables I can be anchored or otherwise secured to the entry plate 172 before the entry plate 172 is secured to the outer housing 102. In certain examples, connectors (e.g., electrical connectors such as a ground lug 178) also can be mounted to the entry plate 172. In certain examples, surge arresters 176 or other components can be mounted to the entry plate 172. In certain examples, a user may select from among different types of entry plates 172 based on the desired configuration of the capacitor bank control enclosure 100. In certain examples, the entry plate 172 is mounted to a surface recessed within the outer housing 102. By mounting the entry plate 172 to a recessed surface, water ingress through the cable access port 184 is inhibited.

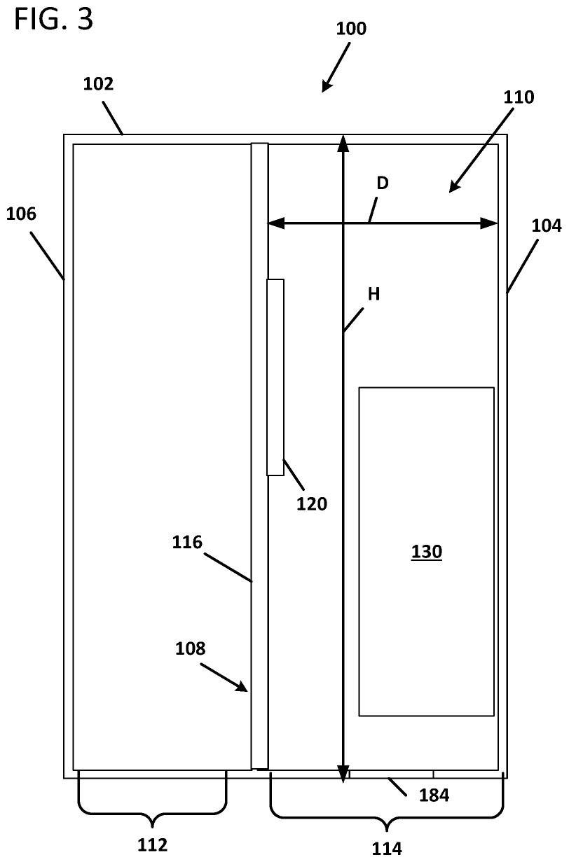

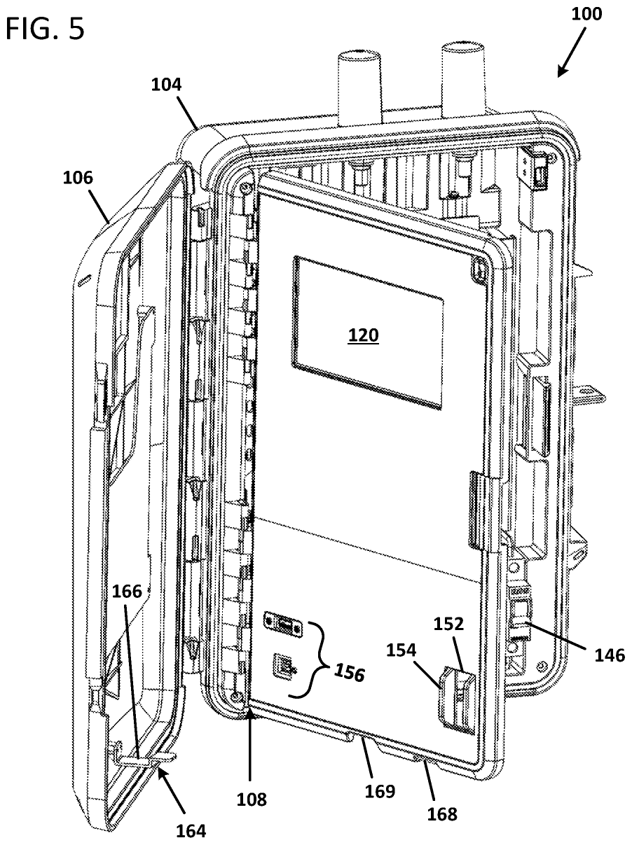

As shown in FIG. 3, an inner door assembly 108 is configured to mount within the outer housing 102. The inner door assembly 108 includes an inner door 116 dividing the interior 110 of the outer housing 102 into a front portion 112 and a rear portion 114. The inner door 116 is movable relative to the outer housing 102 between a blocking position (e.g., see FIG. 4) and an unblocking position (see FIG. 5). The inner door 116 blocks access to the rear portion 114 of the interior 110 when in the blocking position. The inner door 116 allows access to the rear portion 114 of the interior 112 when in the unblocking position. The cover 106 of the outer housing 102 selectively blocks and allows access to the front portion 112 of the interior 110 even when the inner door 116 is disposed in the blocking position.

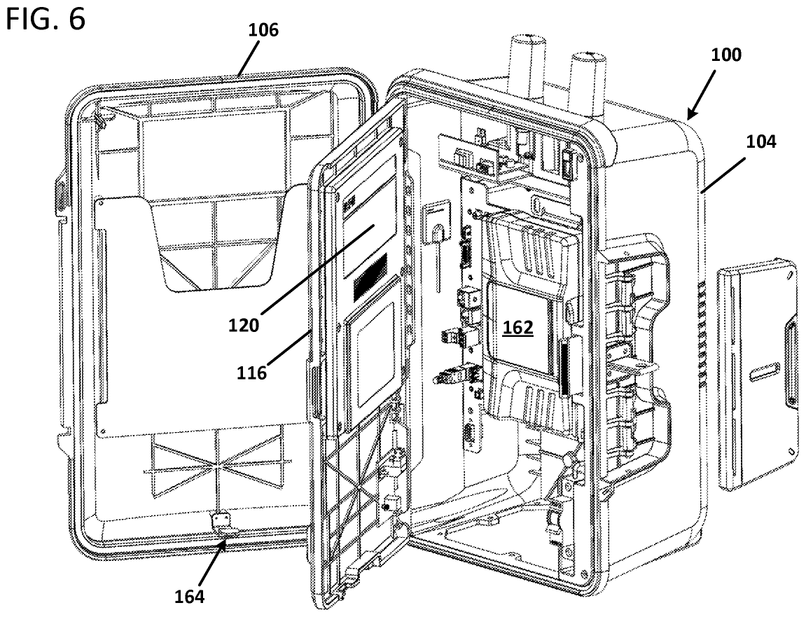

In certain implementations, the inner door assembly 108 carries a display arrangement 120 visible from the front portion 112 of the interior 110. For example, the display arrangement 120 may include an electronic display including a display screen and one or more inputs (e.g., buttons, dials, switches, etc.). In certain examples, the display arrangement 120 is mounted to a rear of the inner door 116 (e.g., see FIG. 6) so that the display is disposed within the rear portion 114 of the interior when the inner door 116 is disposed in the blocking position. In certain examples, the inner door 116 defines an aperture 122 through which the display 120 is visible from the front portion 112 of the interior even when the inner door 116 is disposed in the blocking position.

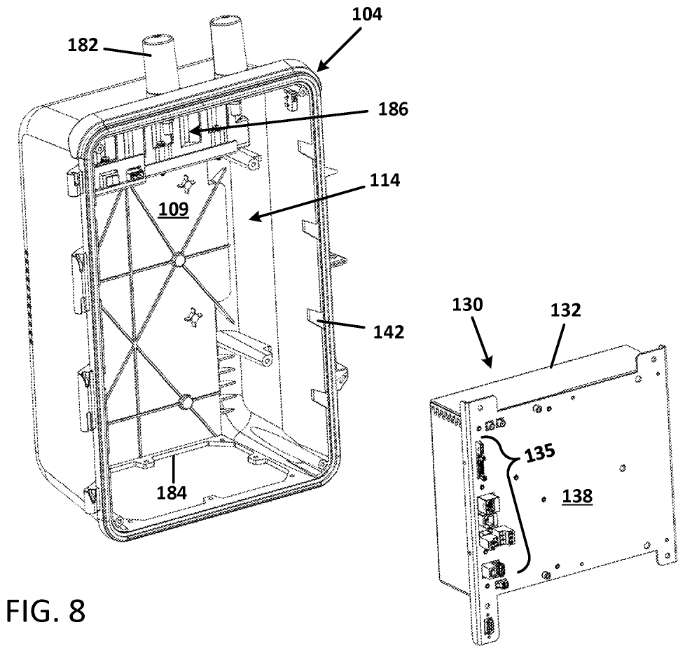

In certain implementations, a modular PCB closure 130 is configured to mount within the rear portion 114 of the outer housing 102 (e.g., see FIG. 8). The inner door assembly 108 blocks access to the modular PCB closure 130 when the inner door 116 is disposed in the blocking position. The inner door assembly 108 allows access to the modular PCB closure 130 when the inner door 116 is disposed in the unblocking position. In certain implementations, enabling the PCT closure 130 to be replaced as a unit allows the PCB closure 130 to be swapped into a new enclosure 100. For example, the PCB closure 130 can be removed from a damaged enclosure 100 and placed into a new, undamaged enclosure 100. Alternatively, the PCB closure 130 can be removed from an older enclosure 100 and remounted in an upgraded enclosure 100. In other examples, a faulty PCB closure 130 can be removed from an enclosure 100 and a replacement PCB closure 130 can be mounted within the enclosure 100 instead of needing to replace the entire enclosure 100.

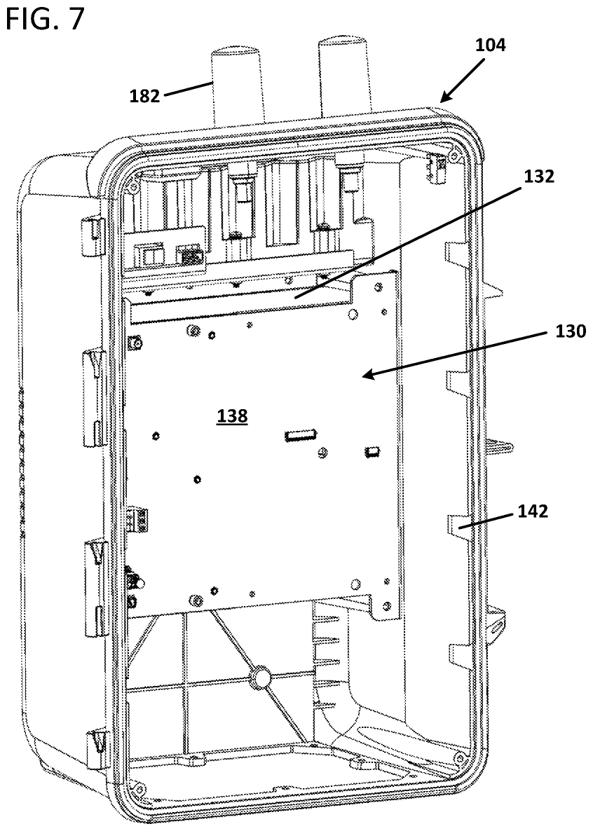

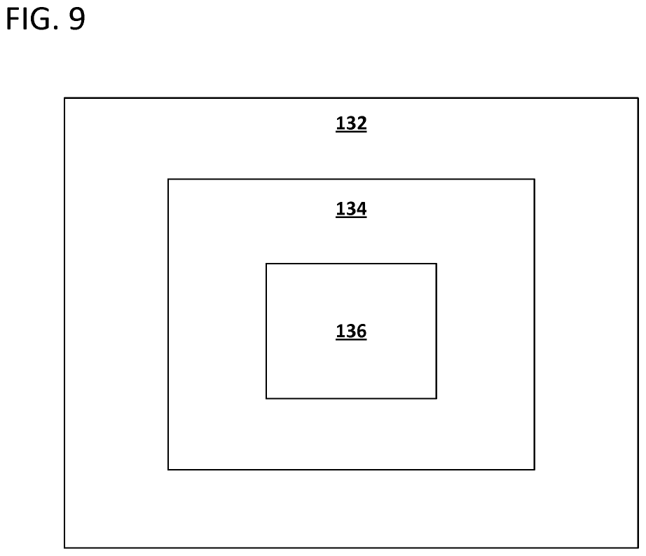

The modular PCB closure 130 includes a closed housing 132 containing a circuit board 134 and a capacitor bank controller 136 mounted to the circuit board 134 (e.g., see FIG. 9). The modular PCB closure 130 is removable from the outer housing 102 as a unit while the inner door 116 is disposed in the unblocking position (e.g., see FIG. 7). In certain implementations, the closed housing 132 of the modular PCB closure 130 includes metallic cover 138. In certain examples, the metallic cover 138 provides a Faraday cage for the capacitor bank controller 136 and/or other components contained within the closed housing 132. In certain examples, the closed housing 132 includes a handle by which the closed housing 132 can be manipulated as a unit.

In certain implementations, the modular PCB closure 130 includes various connectors and/or connector ports 135 extending through the closed housing 132 (e.g., see FIG. 8). For example, the connector ports 135 may include a serial input port, a power supply port, etc. The connectors and/or connector ports 135 enable connection to the capacitor bank controller 136 without disassembling the closed housing 102. In certain examples, the connectors and/or connector ports 135 extend through the metallic cover 138. In certain examples, access to the connectors and/or connector ports 135 from the front portion 112 of the outer housing 102 is blocked by the inner door assembly 108 when the inner door 116 is disposed in the blocking position.

In certain implementations, the cable access port 184 is defined in the base 104 behind the inner door assembly 108. In certain examples, the cables, connectors, and other components carried by the entry plate 170 are disposed in the rear portion 114 of the outer housing interior 110 when the entry plate 170 is mounted at the cable access port 184. In certain examples, access to the cables, connectors, and other components carried by the entry plate 108 are blocked from the front portion 112 of the interior 110 by the inner door assembly 108 when the inner door 116 is disposed in the blocking position.

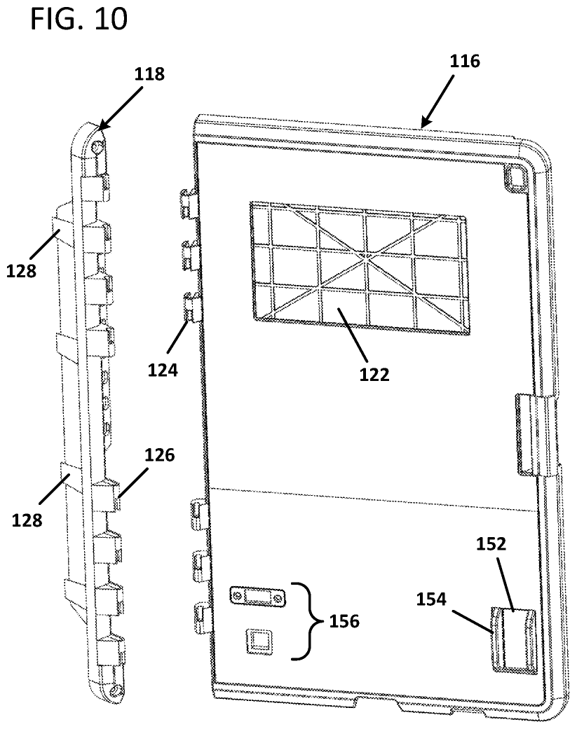

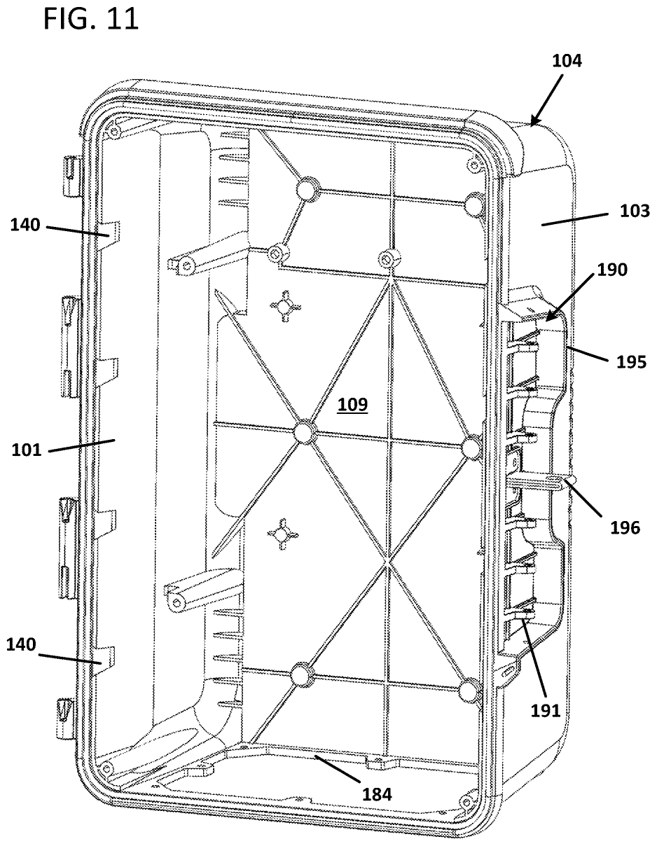

Referring now to FIGS. 10-12, in certain implementations, the inner door assembly 108 is removably mounted to the outer housing 102 as a unit. For example, the inner door assembly 108 can be removed from the outer housing 102 without disassembling the inner door assembly 108. In certain examples, the inner door assembly 108 includes a bracket 118 to which the inner door 116 is mounted. The bracket 118 is removably mountable to the outer housing 102 while the inner door 116 remains attached to the bracket 118. In certain examples, the bracket 118 is configured to slide into mounting engagement with the outer housing 102. In certain examples, the bracket 118 can be further secured in position with one or more removable fasteners (e.g., screws). Enabling replacement of the inner door assembly 108 facilitates replacement of the display arrangement 120 or other component carried by the inner door assembly 108 without needing to replace the entire enclosure 100.

In certain implementations, the bracket 118 includes a first part 128 of a securement arrangement while the outer housing 102 defines a second part 140 of the securement arrangement. The inner door assembly 108 mounts to the outer housing 102 when the first and second parts 128, 140 of the securement arrangement engage each other. In certain examples, one of the first and second parts 128, 140 of the securement arrangement include protrusions and the other of the first and second parts 128, 140 include recesses into which the protrusions fit. In an example, the protrusions and recesses are dovetailed.

The inner door 116 is movable between the unblocking and blocking positions relative to the bracket 118. For example, the inner door 116 includes a first part 124 of a hinge arrangement and the bracket 118 includes a second part 126 of the hinge arrangement (e.g., see FIG. 10). The hinge arrangement defines a pivot axis P along which the inner door 116 pivots between the blocking and unblocking positions (e.g., see FIG. 4). The bracket 118 can be removed from the outer housing 102 (e.g., the first and second parts 128, 140 of the securement arrangement can be detached) while the hinge arrangement remains assembled.

In certain implementations, the bracket 118 is a first bracket that mounts to the first side 101 of the outer housing 102. In certain implementations, the inner door assembly 108 spans the width W of the base 104 at the open front. In certain examples, the inner door assembly 108 spans the height of the base 104 at the open front. In certain examples, the inner door 116 of the inner door assembly 108 spans at least a majority of the width W of the base 104 at the open front of the base 104. In certain examples, the inner door 116 of the inner door assembly 108 spans at least a majority of the height H of the base 104 at the open front of the base 104.

In certain implementations, the inner door assembly 108 allows access to one or more ports 156 carried by the inner door 116 (e.g., see FIGS. 4 and 5). The ports 156 connect (e.g., electrically connect) to components disposed in the rear portion 114 of the outer housing 102. The inner door 116 blocks access to those components when disposed in the blocking position. However, the ports 156 allow electrical connection to those components from the front portion 112 of the outer housing 102 even when the inner door 116 is disposed in the blocking position.

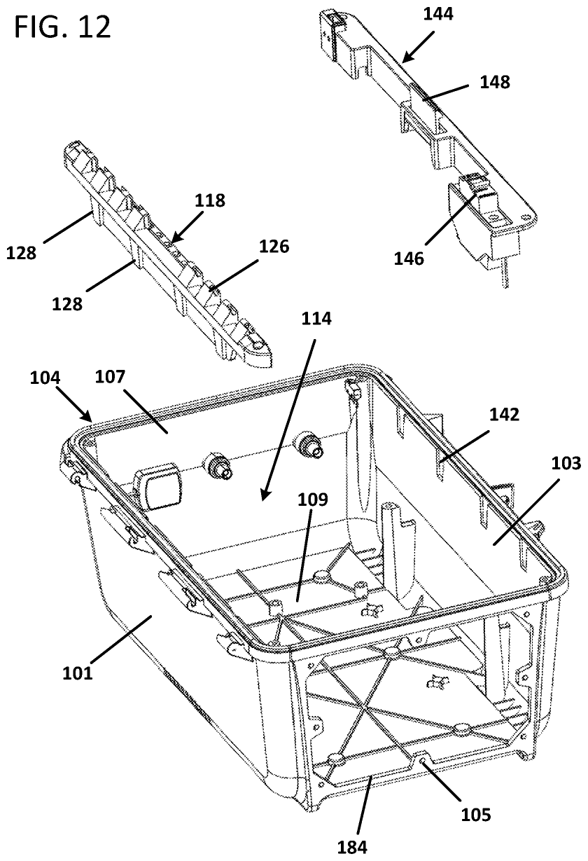

Referring to FIGS. 12 and 13, in certain implementations, a second bracket 144 is configured to mount to the outer housing 102 to secure one or more components within the rear portion 114 of the outer housing 102. In certain examples, the second bracket 144 mounts to the second side 103 of the base 104 opposite the first bracket 118. In certain examples, the second bracket 144 carries the one or more components and is removably secured to the base 104 with the one or more components as a unit. In certain examples, the inner door 116 extends over the second bracket 144 to enclose the second bracket 144 within the rear portion 114 of the outer housing 102 when the inner door 116 is disposed in the blocking position.

For example, the second bracket 144 may include a first part 150 of a securement arrangement while the outer housing 102 defines a second part 142 of the securement arrangement. The second bracket 144 mounts to the outer housing 102 when the first and second parts 150, 142 of the securement arrangement engage each other. In certain examples, one of the first and second parts 150, 142 of the securement arrangement include protrusions and the other of the first and second parts 150, 142 include recesses into which the protrusions fit. In an example, the protrusions and recesses are dovetailed. In certain examples, the securement arrangement of the second bracket 144 is the same as the securement arrangement of the first bracket 118.

In certain implementations, one of the components carried by the second bracket 144 includes a breaker switch 146. The breaker switch 146 allows for power to the enclosure 100 to be switched off during maintenance in the field. In certain implementations, the inner door 116 is configured to enable access to the breaker switch 146 from the front portion 112 of the outer housing 102 even when the inner door 116 is disposed in the blocking position and, thereby, blocking access to the breaker disposed in the rear portion 114 of the interior 110. In certain examples, the inner door 116 defines an aperture 152 through which a portion of the breaker switch 146 may protrude into the front portion 112. In certain examples, the inner door 116 may also define guard flanges 154 extending forwardly of the aperture 152 to inhibit accidental actuation of the breaker switch 146 from the front portion 112.

In certain implementations, one of the components carried by the second bracket 144 includes a door lock 148 for the inner door 116. The door lock 148 assists in holding the inner door 116 in the blocking position. In certain examples, the door lock 148 includes a cantilevered latch defining a hooked distal end that catches on a portion of the inner door 116 when the inner door 116 is disposed in the blocking position. In such examples, the inner door 116 can be unlocked and moved to the unblocking position by flexing or otherwise moving the hooked distal end of the cantilevered latch to release the inner door 116.

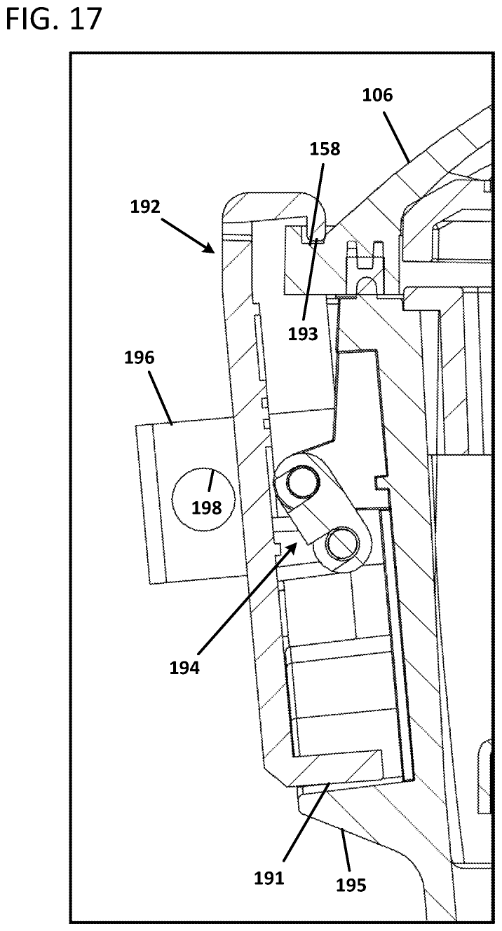

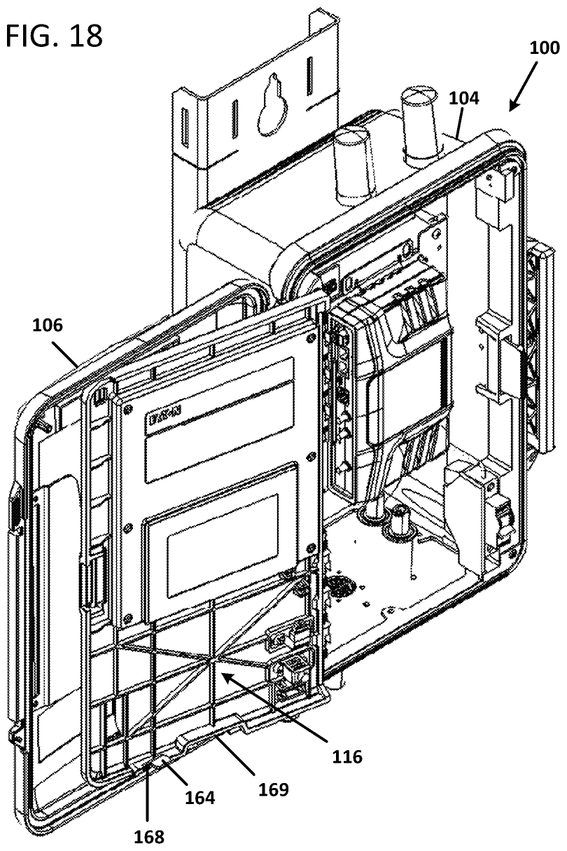

In some implementations, the inner door 116 is freely movable once unlatched from the blocking position. In other implementations, however, the cover 106 may include a door stay 164 configured to arrest movement of the inner door 116 relative to the cover 106 when the cover 106 and the inner door 116 are disposed in the open and unblocking positions, respectively. In certain examples, the door stay 164 including a cantilevered flange defining a dip 166 sized to receive a notched section 168 of the inner door 116. Accordingly, when the cover 106 is open, the inner door 116 can be moved to the unblocking position and engaged with the cover 106 to retain the inner door 116 in the unblocking position (e.g., see FIG. 18). Because the cover 106 and inner door 116 pivot about adjacent pivot axes, the cover 106 and inner door 116 cannot freely swing once so joined.

The inner door 116 can be moved back to the blocking position by deflecting the cantilevered flange to release the notched section 168 of the inner door 116 from the dip 166. When the inner door 116 is disposed in the blocking position, the door stay 164 engages a second notch 169 in the inner door 116 when the cover 106 is closed. In certain examples, the second notch 169 is more centrally located on the inner door 116 than the notch 168. In certain examples, the notch 168 is offset along the width W from a center of the inner door assembly 108 away from the hinge arrangement.

In certain examples, one of the components carried by the second bracket 144 includes a door sensor 152. The door sensor 152 defines a receptacle into which an extension of the inner door 116 protrudes when the inner door 116 is disposed in the blocking position. In some examples, the extension completes a circuit when it extends into the receptacle. In other examples, the extension breaks a circuit when it extends into the receptacle. Accordingly, a controller or other processor electrically connected to the door sensor 152 can monitor whether the inner door 116 is disposed in the blocking position. The controller or other processor may communicate with a door alarm (e.g., a visual alarm, an auditory alarm, an electronic notification such as text, email, or the like, etc.) to indicate when the inner door 116 is not in the blocking position (e.g., at any time, for a predetermined period of time, or at a time when the cover 106 is closed).

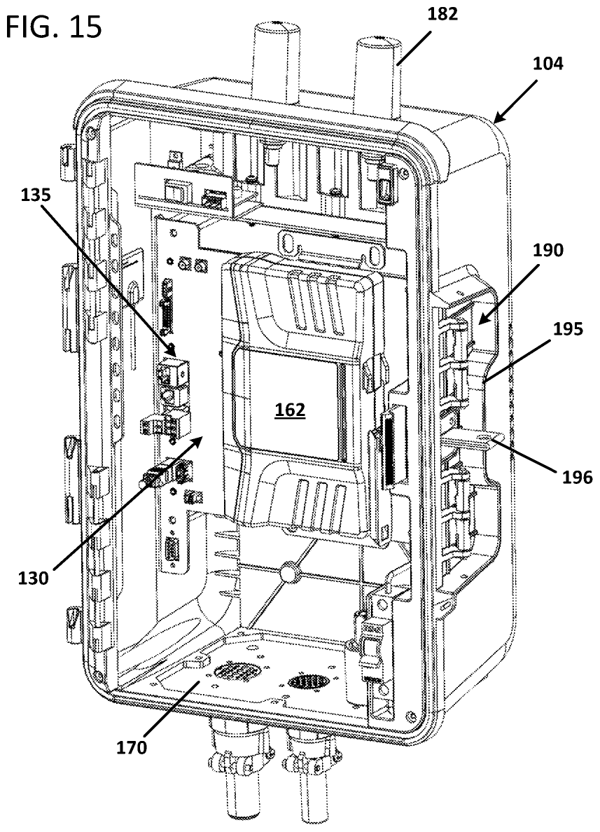

Referring now to FIGS. 14 and 15, a radio mounting station 160 is disposed in the rear portion 114 of the outer housing 102. In certain implementations, the radio mounting station 160 is disposed on the modular PCB closure 130. For example, the radio mounting station 160 may be disposed on the metallic cover 138 of the modular PCB closure 130. A radio (e.g., modem) 162 may be mounted at the radio mounting station 160. The radio 162 is enclosed within the rear portion 114 of the outer housing 102 when the inner door 116 is disposed in the blocking position.

In some implementations, the outer housing 102 defines an antenna mounting region 180 at which one or more antenna 182 can be mounted through the outer housing 102. In the example shown, two antenna 182 are disposed at the antenna mounting region 180. Other configurations are possible. In certain examples, the antenna mounting region 180 is disposed at the top 107 of the outer housing 102. In certain examples, the antenna mounting region 180 is disposed at a top of the base 104. In certain examples, the antenna 182 extends through the base 104 and into the rear portion 114 of the interior 110. In certain examples, access to an interior end of each antenna 182 is blocked from the front portion 112 of the outer housing 102 by the inner door assembly 108 when the inner door 116 is disposed in the blocking position. In certain examples, an interior portion of an antenna 182 is aligned with the radio mounting station 160 to facilitate cabling to a radio or model mounted at the radio mounting station 160.

In certain examples, the antenna mounting region 180 (e.g., the top of the base 104) tapers inwardly as the region extends towards the rear of the enclosure 100 to inhibit water ingress at the antenna mounting region 180. For example, the taper may facilitate water run-off away from the antenna arrangement. In certain examples, the antenna mounting region 180 may taper between 2 degrees and 15 degrees. In certain examples, the antenna mounting region 180 may taper between 4 degrees and 10 degrees. In certain examples, the antenna mounting region 180 may taper between 5 degrees and 8 degrees. In an example, the antenna mounting region 180 may taper inwardly by about six degrees as the antenna mounting region 180 extends rearwardly. In certain examples, the antenna mounting region 180 may taper from the concave pocket 235 of the handle 230 to a rear wall of the base 104.

In other implementations, an antenna arrangement can be mounted at a location spaced from the outer housing 102. In such implementations, a cable extending from the antenna arrangement extends into the outer enclosure 102 (e.g., through the cable access port 116). For example, the cable may electrically connect to a surge arrester 176 disposed within the rear portion 114 of the outer housing 102.

In certain implementations, a power back-up 186 is disposed within the outer housing 102 (e.g., see FIG. 14). The power back-up 186 is sized and configured to provide sufficient power to the capacitor bank controller 136 to continue performing fault detection even in the event of the loss of externally supplied power. In certain examples, the power back-up 186 is configured to provide sufficient power to the radio/modem to enable fault notification even in the event of the loss of externally supplied power. In certain implementations, the power back-up 186 is disposed in the rear portion 114 of the outer housing interior 110. In certain examples, access to the power back-up 186 is blocked from the front portion 112 of the outer housing 102 by the inner door assembly 108 when the inner door 116 is disposed in the blocking position. In certain examples, the power back-up 186 can be mounted on a shelf within the rear portion 114 of the interior 110. In some examples, the power back-up 186 includes one or more supercapacitors. In other examples, the power back-up 186 includes a battery.

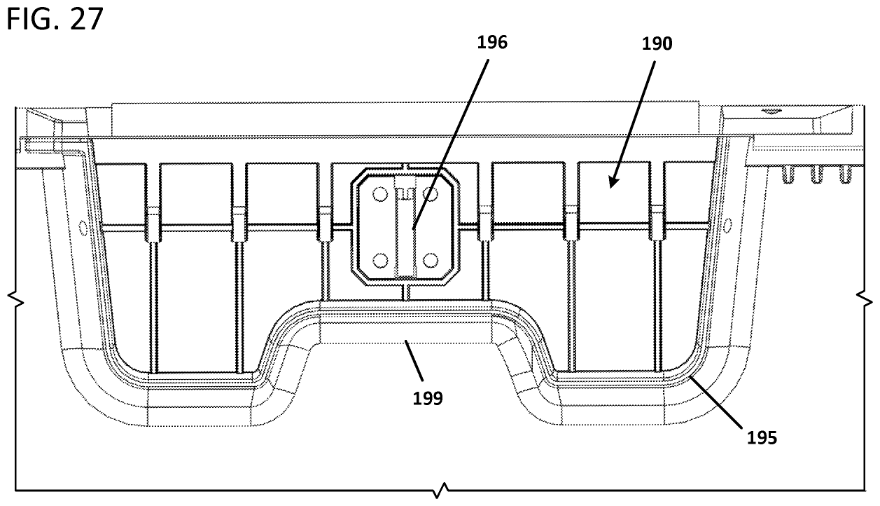

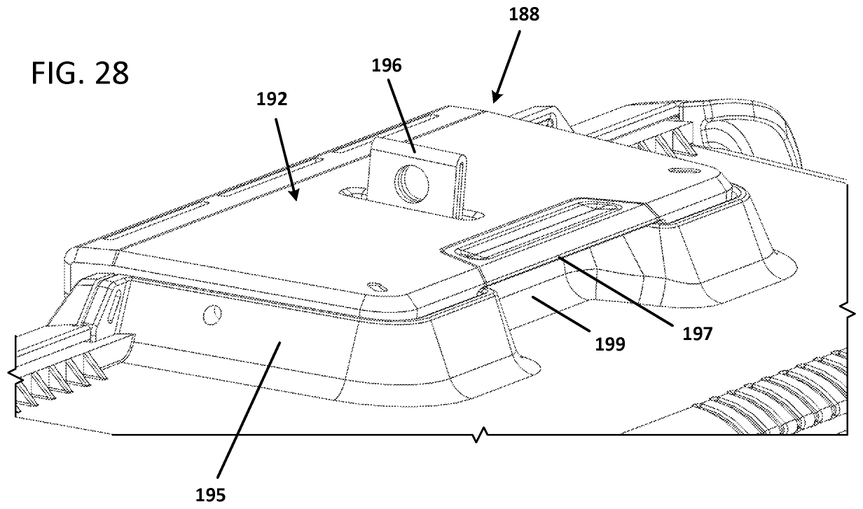

Referring to FIGS. 15-17, 27, and 28, the cover 106 can be secured to the base 104 using a lock arrangement 188. The lock arrangement 188 includes a pocket 190 disposed at an exterior of the base 104 (e.g., see FIGS. 15 and 27). A handle 192 mounts to the base 104 at the pocket 190 (e.g., see FIG. 28). The handle 192 defines a catch surface 193 configured to selectively engage the cover 106 (e.g., a catch surface 158 of the cover 106) to releasably secure the cover 106 in the closed position relative to the base 104 (e.g., see FIG. 17). In certain examples, the handle 192 mounts to the base 104 using an over-center latch 194.

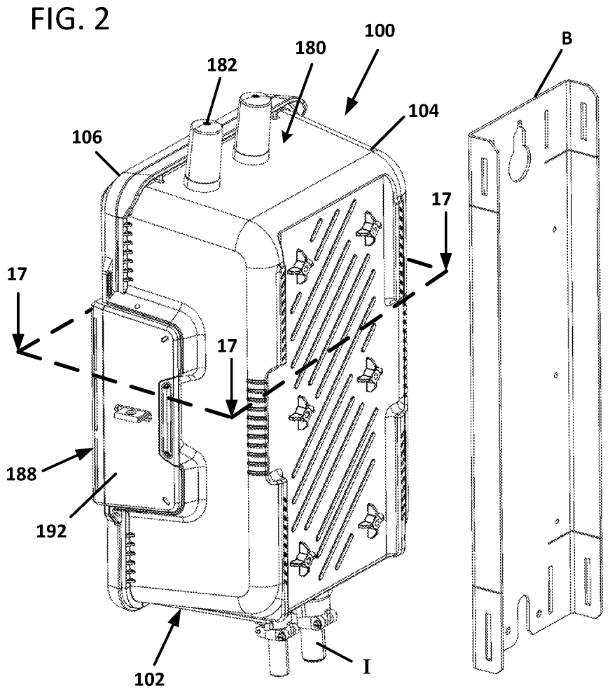

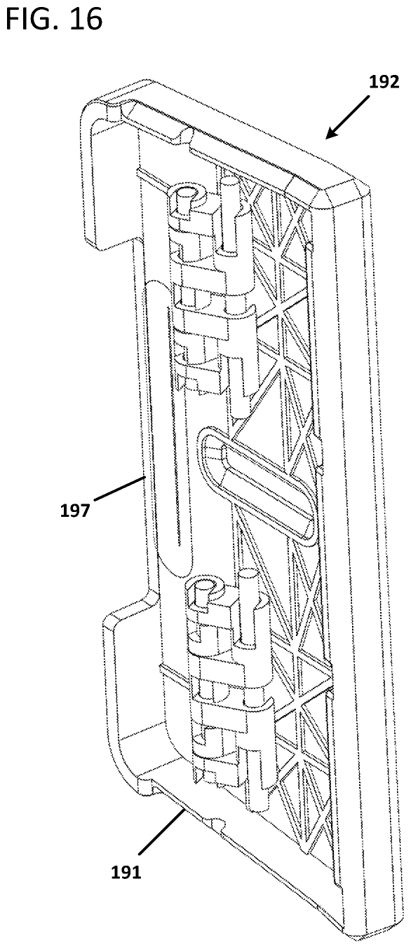

In certain implementations, a wall 195 surrounds at least part of the periphery of the pocket 190. For example, the wall 195 may extend about a top, rear, and bottom of the pocket 190. In certain examples, when the handle 192 is securing the cover 106 in the closed position, the handle 192 seats within the pocket 190 so that the wall 197 overlaps at least part of a peripheral wall 191 of the handle 192 (e.g., see FIG. 2). Such an overlap inhibits ingress into the pocket 190 by animals (e.g., insects, beavers, racoons, etc.). In certain implementations, the handle 192 defines a notched region 197 in the peripheral wall 191 (e.g., see FIG. 16). In certain examples, the wall 195 juts into the pocket to define a recessed region 199 (e.g., see FIG. 27). In certain examples, the notched region 197 of the handle 192 aligns with the recessed region 199 of the pocket 190 to provides finger access for the handle 192 without providing an ingress path into the pocket 190 (e.g., see FIG. 28).

In certain implementations, the enclosure 100 includes only one handle 192 and only one pocket 190. Accordingly, the cover 106 can be released to move to the open position by manipulating of only the one handle 192. In certain examples, the handle 192 spans at least a quarter of the height H of the outer housing 102. In certain examples, the handle 192 spans at least a third of the height H of the outer housing 102. In certain examples, the handle 192 is coupled to the base 104 via two separate hinge arrangements (e.g., see FIG. 16). In certain examples, a flange 196 extends outwardly from the lock station 190 between the two hinge arrangements 194. The flange 196 defines an aperture 198 at which a lock can be secured to inhibit a releasing motion of the handle 192.

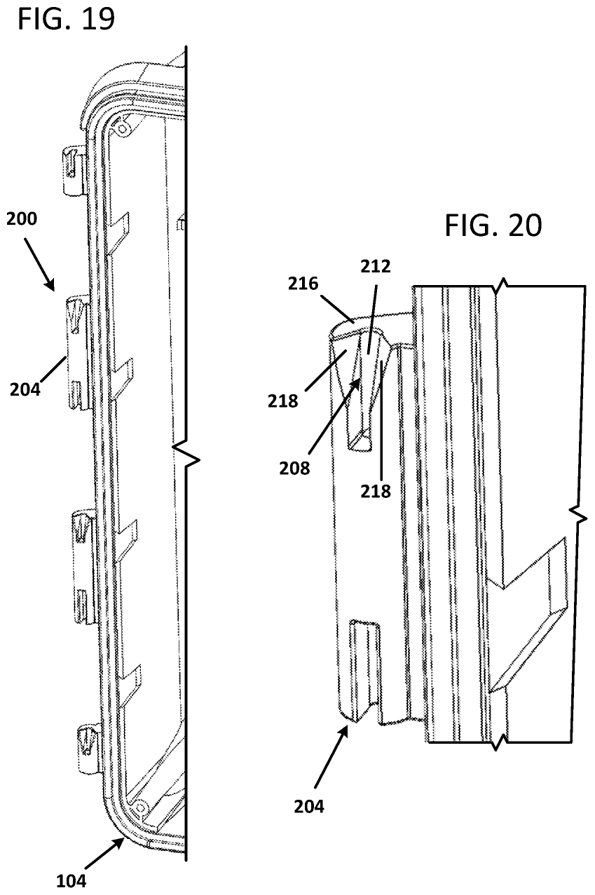

Referring to FIGS. 19-25, the cover 106 can be mounted to the base 104 so that the cover 106 automatically locks into a particular position relative to the base 104. For example, the mounting structure of the cover 106 and the base 104 can be configured to automatically lock the cover 106 in the open position. In an example, the cover 106 can be configured to automatically lock relative to the base 104 when the cover is pivoted about 180 degrees relative to the closed position.

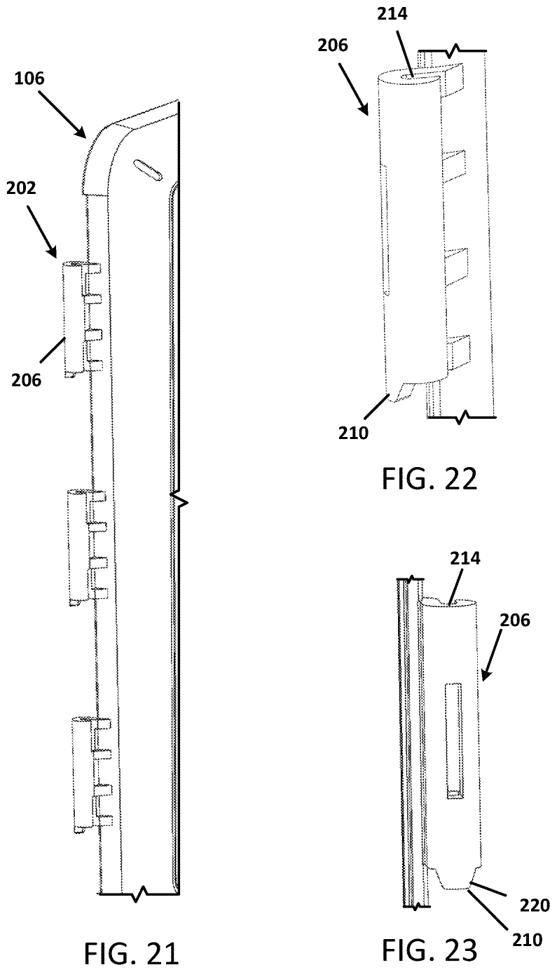

In certain implementations, the mounting structure between the cover 106 and the base 104 includes a hinge arrangement having a first part 200 carried by the base 104 (e.g., see FIG. 19) and a second part 202 carried by the cover 106 (e.g., see FIG. 21). The first part 200 of the hinge arrangement includes a first hinge member 204 (e.g., see FIG. 20) and the second part 202 of the hinge arrangement includes a second hinge member 206 (e.g., see FIGS. 22 and 23). Each of the first and second hinge members 204, 206 defines a channel 212, 214, respectively, along which a hinge pin extends to align the first and second hinge members 204, 206 together. Accordingly, the second hinge member 206 can rotate or pivot about the hinge pin relative to the first hinge member 204 as the cover 106 is moved between the closed and open positions.

In certain implementations, one of the first and second hinge members 204, 206 defines a notch 208 and the other of the hinge members 204, 206 includes a protrusion 210. In the example shown, the first hinge member 204 defines the notch 208 and the second hinge member 206 includes the protrusion 210. The notch 208 is located at one circumferential location of the first hinge member 204 while a sold surface 216 is located at the opposite circumferential location of the first hinge member 204. As shown in FIG. 20, the notch 208 has an open end at a top of the first hinge member 204.

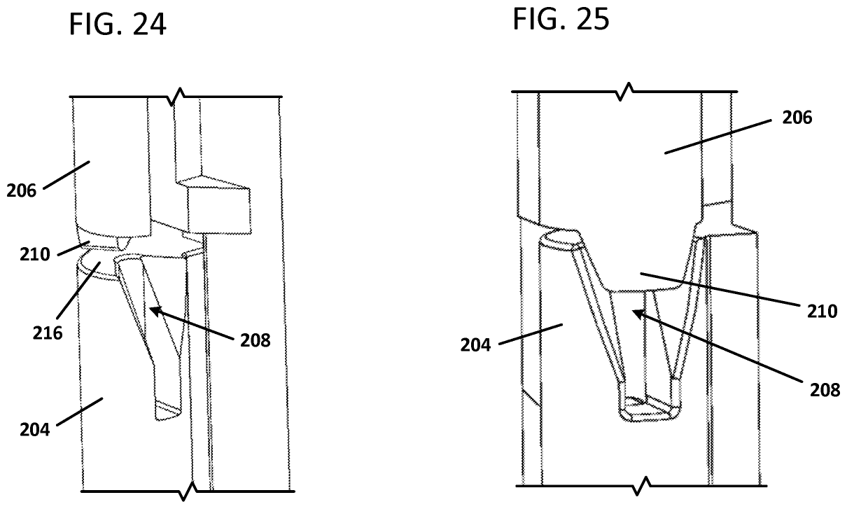

As shown in FIG. 24, the protrusion 210 of the second hinge member 206 seats on the solid surface 216 of the first hinge member 204 when the cover 106 is disposed in the closed position. When the cover 106 is opened, however, the protrusion 210 aligns with the notch 208, thereby allowing the protrusion 210 to drop into the notch 208 (e.g., see FIG. 25). Engagement of the protrusion 210 within the notch 208 inhibits motion of the cover 106 in either direction (towards the closed position or away from the closed position). Accordingly, the cover 106 can be locked in the open position. In some examples, the fit between the notch 208 and the protrusion 210 causes the protrusion 210 to drop into the notch when aligned via gravity, thereby allowing for automatic locking of the cover 106. In other examples, the fit between the notch 208 and the protrusion 210 allows a user to apply force to move the protrusion 210 into the notch 208, thereby allowing for selective locking of the cover 106 in the open position.

In some implementations, to close the cover 106, the user lifts the cover 106 relative to the base 104 sufficient for the protrusion 210 to clear the notch 208 and then moves the cover 106 to the closed position. In other implementations, however, the cover 106 is closed by pushing the cover towards the closed position with a sufficient amount of force. For example, as shown in FIG. 20, the notch 208 may define a ramped side 218 of the notch 208. Further, as shown in FIG. 23, the notch 208 may define a ramped side 220 configured to cam over the ramped side 218 of the notch 208 upon the application of sufficient force in the closing direction of the cover 106. In certain examples, the notch 208 defines ramped sides 218 at opposite circumferential sides of the notch 208 and the protrusion 210 defines ramped sides 220 at opposite sides of the protrusion 210. In other implementations, the ramped side(s) 218, 220 are used in conjunction with lifting of the cover 106 to move the cover 106 to the closed position.

Certain implementations of the inventive concepts of this disclosure are included the following example aspects.

Aspect 1. A capacitor bank control enclosure comprising:
an outer housing including a base and a cover that cooperate to define an interior, the base defining cable access port, the cover being movable relative to the base between an open position and a closed position, the cover blocking access to the interior when the cover is disposed in the closed position, and the cover allowing access to the interior when the cover is disposed in the open position;
an inner door assembly configured to mount within the outer housing, the inner door assembly including an inner door dividing the interior of the outer housing into a front portion and a rear portion, the inner door being movable relative to the outer housing between a blocking position and an unblocking position, the inner door blocking access to the rear portion of the interior when in the blocking position, and the inner door allowing access to the rear portion of the interior when in the unblocking position, the modular door assembly carrying a display arrangement accessible from the front portion of the interior; and
a modular PCB closure configured to mount within the rear portion of the outer housing, the modular PCB closure including a closed housing containing a circuit board and a capacitor bank controller mounted to the circuit board, the modular PCB closure being removable from the outer housing as a unit while the inner door is disposed in the unblocking position.

Aspect 2. The capacitor bank control enclosure of aspect 1, wherein the closed housing of the modular PCB closure includes metallic cover to provide Faraday cage.

Aspect 3. The capacitor bank control enclosure of aspect 1 or aspect 2, further comprising a radio mounting station disposed in the rear portion of the outer housing.

Aspect 4. The capacitor bank control enclosure of aspect 3, wherein the radio mounting station is disposed on the modular PCB closure.

Aspect 5. The capacitor bank control enclosure of any of aspects 1-4, wherein the inner door assembly includes an elongate bracket to which the inner door is mounted, the elongate bracket being removably mountable to the outer housing, the inner door being movable between the unblocking and blocking positions relative to the elongate bracket.

Aspect 6. The capacitor bank control enclosure of aspect 5, wherein the elongate bracket is slidably mounted to the outer housing using dovetails.

Aspect 7. The capacitor bank control enclosure of aspect 5, wherein the inner door pivots relative to the elongate bracket between the closed and open positions, wherein the inner door assembly is removable from the outer housing as a unit without removing a hinge pin between the inner door and the elongate bracket.

Aspect 8. The capacitor bank control enclosure of any of aspects 1-7, further comprising a breaker switch configured to mount within the rear portion of the interior.

Aspect 9. The capacitor bank control enclosure of aspect 8, wherein the breaker switch is accessible from the front portion of the interior even when the inner door is disposed in the blocking position through an aperture defined in the inner door.

Aspect 10. The capacitor bank control enclosure of aspect 9, wherein the inner door includes guard flanges disposed at opposite sides of the aperture.

Aspect 11. The capacitor bank control enclosure of aspect 8, wherein the breaker switch is mounted to an elongate bracket that is slidably mounted to the outer housing.

Aspect 12. The capacitor bank control enclosure of any of aspects 1-11, wherein the inner door assembly includes a first bracket that is slidably mounted to a first side of the outer housing, wherein a second bracket is slidably mounted to an opposite, second side of the outer housing, and wherein the inner door mounts to the first bracket and extends across a width of the interior to cover the second bracket when the inner door is disposed in the blocking position.

Aspect 13. The capacitor bank control enclosure of any of aspects 1-12, further comprising a power back-up to provide sufficient power to perform fault detection and notification, the power back-up disposed in the rear portion of the interior.

Aspect 14. The capacitor bank control enclosure of aspect 13, wherein the power back-up includes a supercapacitor.

Aspect 15. The capacitor bank control enclosure of any of aspects 1-14, further comprising a door stay mounted to the cover, the door stay including a cantilevered flange defining a dip sized to receive a notched section of the inner door.

Aspect 16. The capacitor bank control enclosure of any of aspects 1-15, wherein the base includes a handle defined by a rearwardly-facing lip of the base.

Aspect 17. The capacitor bank control enclosure of any of aspects 1-16, wherein the base defines an antenna mounting region, and wherein the base tapers inwardly at the antenna mounting region extends towards a rear of the base; and optionally wherein the base tapers inwardly between the handle and the rear of the base.

Aspect 18. The capacitor bank control enclosure of any of aspects 1-17, further comprising a lock arrangement to secure the cover in the closed position relative to the base, wherein the lock arrangement includes a pocket defined in the base and a handle mounted at the pocket.

Aspect 19. The capacitor bank control enclosure of aspect 18, wherein the pocket is partially bounded by a wall that overlaps with a peripheral wall of the handle when the handle secures the cover in the closed position; and wherein the pocket wall defines a recess and the peripheral wall of the handle defines a notch that aligns with the recess.

Aspect 20. A method of replacing an old capacitor bank controller with a new capacitor bank controller comprising:
opening a cover of a capacitor bank controller enclosure;
moving an inner door assembly of the capacitor bank controller enclosure to access a rear portion of an interior of the capacitor bank controller enclosure;
removing an old PCB closure as a unit from the rear portion of the interior, the old PCB closure including the old capacitor bank controller; and
installing a new PCB closure as a unit within the rear portion of the interior with replacing a remainder of the capacitor bank controller enclosure, the new PCB closure including the new capacitor bank controller.

Having described the preferred aspects and implementations of the present disclosure, modifications and equivalents of the disclosed concepts may readily occur to one skilled in the art. However, it is intended that such modifications and equivalents be included within the scope of the claims which are appended hereto.

What is claimed is:

1. A capacitor bank control enclosure comprising:
an outer housing including a base and a cover that cooperate to define an interior, the base defining cable access port, the cover being movable relative to the base between an open position and a closed position, the cover blocking access to the interior when the cover is disposed in the closed position, and the cover allowing access to the interior when the cover is disposed in the open position;
an inner door assembly configured to mount within the outer housing, the inner door assembly including an inner door dividing the interior of the outer housing into a front portion and a rear portion, the inner door being movable relative to the outer housing between a blocking position and an unblocking position, the inner door blocking access to the rear portion of the interior when in the blocking position, and the inner door allowing access to the rear portion of the interior when in the unblocking position, the modular door assembly carrying a display arrangement accessible from the front portion of the interior; and
a modular PCB closure configured to mount within the rear portion of the outer housing, the modular PCB closure including a closed housing containing a circuit board and a capacitor bank controller mounted to the circuit board, the modular PCB closure being removable from the outer housing as a unit while the inner door is disposed in the unblocking position.

2. The capacitor bank control enclosure of claim 1, wherein the closed housing of the modular PCB closure includes metallic cover to provide Faraday cage.

3. The capacitor bank control enclosure of claim 1, further comprising a radio mounting station disposed in the rear portion of the outer housing.

4. The capacitor bank control enclosure of claim 3, wherein the radio mounting station is disposed on the modular PCB closure.

5. The capacitor bank control enclosure of claim 1, wherein the inner door assembly includes an elongate bracket to which the inner door is mounted, the elongate bracket being removably mountable to the outer housing, the inner door being movable between the unblocking and blocking positions relative to the elongate bracket.

6. The capacitor bank control enclosure of claim 5, wherein the elongate bracket is slidably mounted to the outer housing using dovetails.

7. The capacitor bank control enclosure of claim 5, wherein the inner door pivots relative to the elongate bracket between the closed and open positions, wherein the inner door assembly is removable from the outer housing as a unit without removing a hinge pin between the inner door and the elongate bracket.

8. The capacitor bank control enclosure of claim 1, further comprising a breaker switch configured to mount within the rear portion of the interior.

9. The capacitor bank control enclosure of claim 8, wherein the breaker switch is accessible from the front portion of the interior even when the inner door is disposed in the blocking position through an aperture defined in the inner door.

10. The capacitor bank control enclosure of claim 9, wherein the inner door includes guard flanges disposed at opposite sides of the aperture.

11. The capacitor bank control enclosure of claim 8, wherein the breaker switch is mounted to an elongate bracket that is slidably mounted to the outer housing.

12. The capacitor bank control enclosure of claim 1, wherein the inner door assembly includes a first bracket that is slidably mounted to a first side of the outer housing, wherein a second bracket is slidably mounted to an opposite, second side of the outer housing, and wherein the inner door mounts to the first bracket and extends across a width of the interior to cover the second bracket when the inner door is disposed in the blocking position.

13. The capacitor bank control enclosure of claim 1, further comprising a power back-up to provide sufficient power to perform fault detection and notification, the power back-up disposed in the rear portion of the interior.

14. The capacitor bank control enclosure of claim 13, wherein the power back-up includes a supercapacitor.

15. The capacitor bank control enclosure of claim 1, further comprising a door stay mounted to the cover, the door stay including a cantilevered flange defining a dip sized to receive a notched section of the inner door.

16. The capacitor bank control enclosure of claim 1, wherein the base includes a handle defined by a rearwardly-facing lip of the base.

17. The capacitor bank control enclosure of claim 1, wherein the base defines an antenna mounting region, and wherein the base tapers inwardly at the antenna mounting region extends towards a rear of the base; and optionally wherein the base tapers inwardly between the handle and the rear of the base.

18. The capacitor bank control enclosure of claim 1, further comprising a lock arrangement to secure the cover in the closed position relative to the base, wherein the lock arrangement includes a pocket defined in the base and a handle mounted at the pocket.

19. The capacitor bank control enclosure of claim 18, wherein the pocket is partially bounded by a wall that overlaps with a peripheral wall of the handle when the handle secures the cover in the closed position; and wherein the pocket wall defines a recess and the peripheral wall of the handle defines a notch that aligns with the recess.

20. A method of replacing an old capacitor bank controller with a new capacitor bank controller comprising:
opening a cover of a capacitor bank controller enclosure;
moving an inner door assembly of the capacitor bank controller enclosure to access a rear portion of an interior of the capacitor bank controller enclosure;
removing an old PCB closure as a unit from the rear portion of the interior, the old PCB closure including the old capacitor bank controller; and
installing a new PCB closure as a unit within the rear portion of the interior with replacing a remainder of the capacitor bank controller enclosure, the new PCB closure including the new capacitor bank controller.
